(19) United States
(12) Patent Application Publication
(10) Pub. No.: US 2025/0378862 A1
(43) Pub. Date: Dec. 11, 2025

(54) ASYNCHRONOUS MULTI-LEVEL SIGNAL SAMPLING

(71) Applicant: Micron Technology, Inc., Boise, ID (US)

(72) Inventors: Martin Brox, München (DE); Martin Bach, München (DE); Miljana Nenadovic, München (DE); Hemant Madhewar, München (DE); Mani Balakrishnan, München (DE); Thomas Hein, München (DE)

(21) Appl. No.: 19/221,198

(22) Filed: May 28, 2025

Related U.S. Application Data
(60) Provisional application No. 63/656,819, filed on Jun. 6, 2024.

(51) Int. Cl. G11C 7/22; G06F 1/08; H03K 5/00; H03K 5/133

(52) U.S. Cl. CPC G11C 7/222; G06F 1/08; H03K 5/133; H03K 2005/00019

(57) ABSTRACT

Methods, systems, and devices for asynchronous multi-level signal sampling are described. A system may generate a first clock signal by delaying the master clock signal by a first duration that is based on a first propagation delay associated with a first amplifier for a data signal. The system may generate a second clock signal by delaying the master clock signal by a second duration that is based on a second propagation delay associated with a second amplifier for the data signal. The system may sample, by a first sampling circuit based on the first clock signal, a first amplified data signal outputted by the first amplifier. And the system may sample, by a second sampling circuit based on the second clock signal, a second amplified data signal outputted by the second amplifier.

### CROSS REFERENCE

The present Application for Patent claims priority to U.S. Patent Application No. 63/656,819 by Brox et al., entitled “ASYNCHRONOUS MULTI-LEVEL SIGNAL SAMPLING,” filed Jun. 6, 2024, which is assigned to the assignee hereof, and which is expressly incorporated by reference in its entirety herein.

### TECHNICAL FIELD

The following relates to one or more systems for memory, including asynchronous multi-level signal sampling.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports asynchronous multi-level signal sampling in accordance with examples as disclosed herein.

FIG. 2 shows an example of receive circuitry and related aspects that support asynchronous multi-level signal sampling in accordance with examples as disclosed herein.

FIG. 3 shows an example of clock circuitry that supports asynchronous multi-level signal sampling in accordance with examples as disclosed herein.

FIG. 4 shows a block diagram of a memory system that supports asynchronous multi-level signal sampling in accordance with examples as disclosed herein.

FIG. 5 shows a flowchart illustrating a method or methods that support asynchronous multi-level signal sampling in accordance with examples as disclosed herein.

### DETAILED DESCRIPTION

A system, such as a memory system, may receive information over one or more pins of an interface. The information may be modulated into a multi-level signal according to a modulation scheme such as a pulse amplitude modulation (PAM) scheme that has multiple voltage levels each corresponding to a different symbol representative of multiple bits. To decode the information received over a pin in the form of a multi-level signal, the system may use multiple amplifiers and each amplifier may compare the signal on the pin with a respective reference voltage and amplify the difference (among other operations). The amplified signal outputted by an amplifier may be sampled by a respective sampling circuit so that the value of the amplified signal can be input into, for example, a decoder. So, the system may use multiple amplifiers and sampling circuits to process a multi-level signal.

But the amplifiers may be associated with different propagation delays that cause the amplified signals to arrive at the sampling circuits at different times. In such a scenario, operating the sampling circuits synchronously (e.g., in accordance with a master clock such as a same overall timing) may result in decoding errors if the propagation delays cause the symbols of the amplified signals to be sampled toward or at the edges of the symbols periods instead of toward or at the center of the symbol periods.

According to the techniques described herein, a system that uses multiple amplifiers and sampling circuits to process a multi-level signal may improve decoding by operating the sampling circuits asynchronously. For example, the system may operate a first sampling circuit for a first amplifier according to a first clock signal and may operate a second sampling circuit for a second amplifier according to a second clock signal that is offset in time relative to the first clock signal. The first clock signal may compensate for the propagation delay of the first amplifier (e.g., so that the first amplified signal from the first amplifier is sampled substantially toward or at the centers of the symbol periods of the first amplified signal) and the second clock signal may compensate for the propagation delay of the second amplifier (e.g., so that the second amplified signal from second first amplifier is sampled substantially toward or at the centers of the symbol periods of the second amplified signal). Thus, the sample timing of the sampling circuits may be improved relative to other techniques, which in turn may improve decoding (among other aspects) relative to other techniques.

In addition to applicability in memory systems as described herein, techniques for asynchronous sampling may be generally implemented to support increased connectivity of electronic systems. As the use of systems relying on interconnected electronic devices increases, the connectivity of these electronic devices becomes an increasingly relevant factor for the operations of the system. For example, delays associated with signals communicated between devices may become increasingly relevant as critical systems come to rely more on connectivity, as a system uses larger quantities of interconnected devices, or if the quantity and the complexity of signals communicated between devices increases. Implementing the techniques described herein may support techniques for increased connectivity in electronic systems by improving data transfer between devices, among other benefits.

Features of the disclosure are illustrated and described in the context of systems and architectures. Features of the disclosure are further illustrated and described in the context of circuitry and flowcharts.

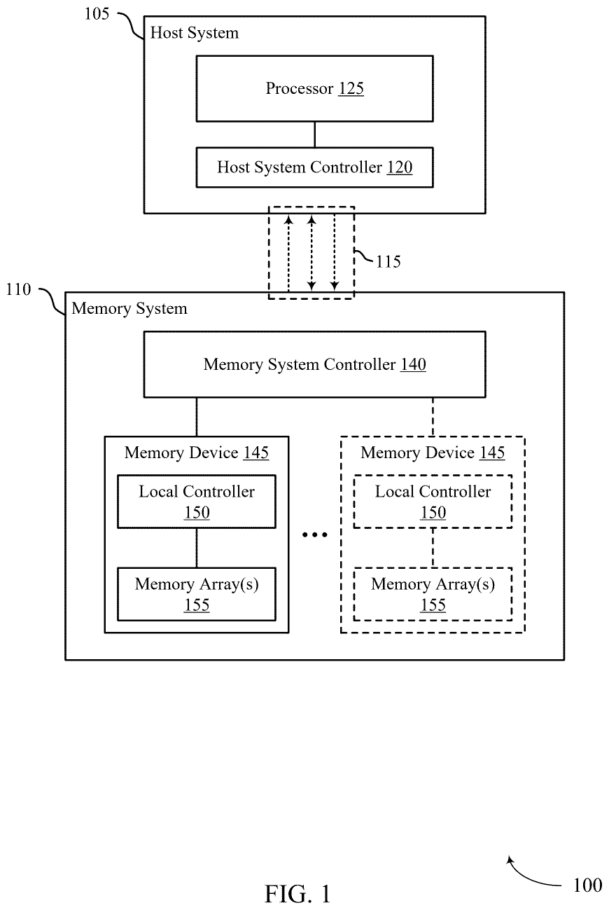

FIG. 1 illustrates an example of a system 100 that supports asynchronous multi- level signal sampling in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

Signaling may be communicated over the channels 115 using single data rate (SDR) signaling or double data rate (DDR) signaling, among other rates (e.g., relative to a clock signal). In SDR signaling, one modulation symbol (e.g., signal level) of a signal may be registered for each clock cycle (e.g., on a rising edge or a falling edge of a clock signal). In DDR signaling, two modulation symbols of a signal may be registered for each clock cycle (e.g., on both a rising edge and a falling edge of a clock signal).

As noted, information may be conveyed between the host system 105 and the memory system 110 via the channels 115, which may terminate at pins on each system. For example, the host system 105 may transmit information to the memory system 110 via a channel 115 that terminates at a pin (e.g., a data pin, a command/address pin) of the memory system 110. Similarly, the memory system 110 may transmit information to the host system 105 via a channel 115 that terminates at a pin (e.g., a data pin, a control pin) of the host system 105. The information exchanged between the host system 105 and the memory system 110 may be in the form of a multi-level signal that is modulated according to a multi-level modulation scheme such as a PAM scheme. A PAM3 scheme may refer to a modulation scheme that includes three voltage levels each corresponding to a respective symbol representative of a multiple bits, whereas a PAM4 scheme may refer to a modulation scheme that includes four voltage levels each corresponding to a respective symbol representative of a multiple bits.

According to the techniques described herein, a system (e.g., the host system 105, the memory system 110) may process a received multi-level signal using a combination of amplifiers and sampling circuits. For example, in a PAM3 scheme, the system may use a first amplifier to provide a first amplified signal (based on the received multi-level signal) to a first sampling circuit and may use a second amplifier to provide a second amplified signal (also based on the received multi-level signal) to a second sampling circuit. The sampling circuits may be operated asynchronously in accordance with respective input clocks that are offset in time relative to each other. For example, the first sampling circuit may be operated in accordance with a first clock signal that is based on (e.g., compensates for) the propagation delay associated with the first amplifier. And the second sampling circuit may be operated in accordance with a second clock signal that is based on (e.g., compensates for) the propagation delay associated with the second amplifier. Thus, the sampling performed by the sampling circuits may be aligned with the symbol periods of the respective amplified signals, which may improve decoding of the multi-level signal, among other advantages.

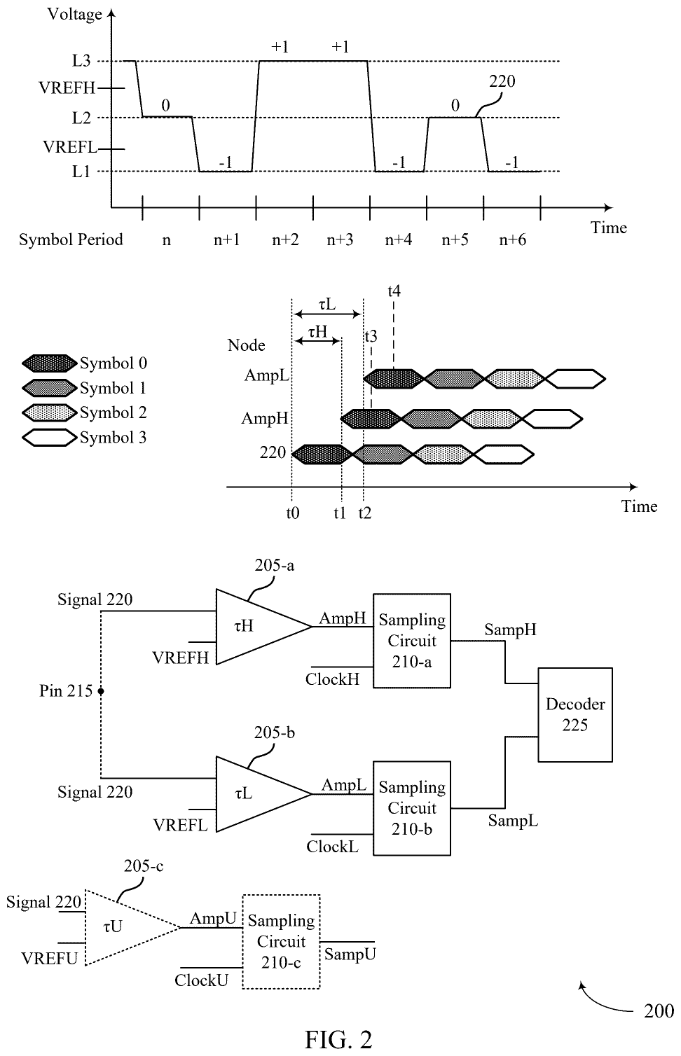

FIG. 2 illustrates an example of receive circuitry 200 that supports asynchronous multi-level signal sampling in accordance with examples as disclosed herein. The receive circuitry 200 may be included in a system such as a host system 105 or a memory system 110 as described herein and with reference to FIG. 1. The receive circuitry 200 may include asynchronously operated sampling circuits 210. The receive circuitry 200 may be used to process a multi-level signal (e.g., signal 220) that is received over a pin (e.g., pin 215) of the system. The sampling circuits 210 may be operated asynchronously (e.g., according to respective two or more clock signals that are offset in time) so that sampling of an amplified signal inputted into a sampling circuit 210 is aligned with the symbol periods of that amplified signal.

The multi-level signal processed by the receive circuitry 200 may be a PAM3 signal, a PAM4 signal, or any type of PAM signal. For example, the signal 220 may be a PAM3 signal that includes three voltage levels (e.g., amplitudes, magnitudes) denoted L1, L2, and L3. In such examples, the system may use reference voltages such as VREFL and VREFH (e.g., a first reference voltage and a second reference voltage) to distinguish between the three voltage levels and each voltage level (e.g., L1, L2, L3) may correspond to a symbol which in turn represents multiple bits. For instance, voltage level L1 may correspond to symbol-1 (which may represent bit values ‘00’), voltage level L2 may correspond to symbol 0 (which may represent bit values ‘01’), and voltage level L3 may correspond to symbol +1 (which may represent bit values ‘11’).

In other examples, the signal 220 may be a PAM4 signal that includes four voltage levels (e.g., L1, L2, L3, and L4, where L4 is higher than L3). In such examples, the system may use reference voltages such as VREFL, VREFH, and VREFU (e.g., a first reference voltage, a second reference voltage, a third reference voltage) to distinguish between the four voltage levels (where VFREU is between L3 and LA). In general, a PAMx signal may include x volage levels that are distinguished using x-1 reference voltages, where x is a positive integer.

One symbol of the signal 220 may occur every symbol period. For example, one symbol may occur in symbol period n, one symbol may occur in symbol period n+1, and so on and so forth. Thus, the symbol periods may divide the signal 220 into symbols. The voltage level of the signal 220 may transition (e.g., go from one voltage level to another) in between symbol periods and may not reach the target voltage level until partway through the symbol period. So, sampling a symbol near the boundaries of the symbol period may result in latched values that are erroneous. Techniques for sampling symbols near the center of their respective symbol periods may be desired.

The receive circuitry 200 may receive and process a multi-level signal such as the signal 220. The signal 220 may be a data signal, a control signal (e.g., a command, an address), or any type of signal. At a high level, the amplifiers 205 may receive the signal 220, compare the voltage level of the signal 220 with respective reference voltages (e.g., VREFH, VREFL), and output respective amplified signals (e.g., AmpH, AmpL) based on the comparison. The sampling circuits 210 may sample the amplified signals according to respective input clocks (e.g., ClockH, ClockL) and output sampled values (e.g., AmpH, AmpL). Use of respective input clocks to control the sample timing of the sampling circuits 210 may improve the accuracy of the output sampled values. The decoder 225 may determine the symbols of the signal 220 based on the sampled values.

A more detailed description of the receive circuitry 200 is included herein.

As noted, the receive circuitry 200 may receive and process a multi-level signal such as the signal 220. For example, the signal 220 may be received at pin 215, which may be coupled with an input terminal of the amplifier 205-a and with an input terminal of the amplifier 205-b. So, in some examples an input terminal of the amplifier 205-a may be coupled with an input terminal of the amplifier 205-b.

Each amplifier 205 may be configured to receive a respective reference voltage to compare with the signal 220. For example, an input terminal of the amplifier 205-a may be configured to receive (e.g., from a first reference voltage source) reference voltage VREFH. And an input terminal of the amplifier 205-a may be configured to receive (e.g., from a second reference voltage source) reference voltage VREFL. Amplifier 205-a may compare the signal 220 with the reference voltage VREFH, amplify the voltage difference between signal 220 and the reference voltage VREFH, and output amplified signal AmpH. Similarly, amplifier 205-b may compare the signal 220 with the reference voltage VREFL, amplify the voltage difference between signal 220 and the reference voltage VREFL, and output amplified signal AmpL.

The amplifiers 205 may have different configurations (e.g., due to the different reference voltages) and thus may have associated propagation delays that are different, where the propagation delay of a component refers to the amount of time it takes for a signal received at the component to be outputted by the component. For example, amplifier 205-a may have a first propagation delay (e.g., propagation delay TH) and amplifier 205-b may have a second propagation delay (e.g., propagation delay TL) that is different from (e.g., longer than, shorter than) the first propagation delay. If the propagation delays of the amplifiers 205 are different, the amplifiers 205 may output respective amplified signals for a symbol of the signal 220 at different times even though amplifiers 205 received the symbol at the same time.

To illustrate, reference is made to the middle figure which shows the symbol periods of four symbols (Symbol 0, Symbol 1, Symbol 2, Symbol 3) of the signal 220, the amplified signal AmpH, and the amplified signal AmpL. Considering Symbol 0, which may be received by the amplifiers 205 at time t0, the amplified signal AmpH may be outputted by amplifier 205-a at a time t1 (e.g., after a delay equal to propagation delay τH). Still referring to Symbol 0, the amplified signal AmpL may be outputted by amplifier 205-b at a time t2 (e.g., after a delay equal to propagation delay τL).

Accordingly, the amplified signals outputted by the amplifiers 205 may be received at different times by the sampling circuits 210. Rather than operating the sampling circuits 210 synchronously so that the amplified signals are sampled at the same time, the sampling circuits 210 may be operated asynchronously so that the amplified signals are sampled at different times. In this way, the amplified signals can be sampled near the center of their respective symbol periods even though the amplified signals are offset in time. As noted, for a given symbol, the target voltage level may not be reached until partway through the symbol period. So, sampling a symbol near the center of the symbol period (e.g., toward or at midway between the end points of the symbol period) may increase the accuracy of the values latched by the sampling circuits 210.

The sampling circuits 210 may be operated asynchronously by operating the sampling circuits 210 according to different input clocks. For example, sampling circuit 210-a may be operated according to a first clock signal (e.g., ClockH) and sampling circuit 210-b may be operated according to a second clock signal (e.g., ClockL). Sampling circuit 210-a may be operated according to ClockH by being configured to use the transitions of ClockH as triggers for sampling the amplified signal AmpH. Similarly, sampling circuit 210-b may be operated according to ClockL by being configured to use the transitions of ClockL as triggers for sampling the amplified signal AmpL.

ClockH may be derived from (e.g., generated from) a master clock signal and may have a delay relative to the master clock signal that is based on (e.g., equal to) the propagation delay τH. Thus, the timing of sampling the amplified signal AmpH may compensate for the propagation delay τH of the amplifier 205-a. ClockL may be derived from (e.g., generated from) the master clock signal and may have delay relative to the master clock signal that is based on (e.g., equal to) the propagation delay τL. Thus, the timing of sampling the amplified signal AmpL may compensate for the propagation delay τL of the amplifier 205-b. Sampling a signal may refer to measuring a value (e.g., voltage level) of the signal and latching or outputting that value (e.g., voltage level) at an output terminal.

The sampling circuits 210 may be coupled with the decoder 225, which may also be referred to as a demodulator, and may output sampled values to the decoder 225 for decoding. For example, an output terminal of the sampling circuit 210-a and an output terminal of the sampling circuit 210-b may each be coupled with the decoder 225. For a given symbol period, the decoder 225 may be configured to receive the sampled value (e.g., SampH) from sampling circuit 210-a and the sampled value (e.g., SampL) from sampling circuit 210-b and determine the symbol for that symbol period based on the combination of sampled values.

For example, for Symbol n, if SampH is +1 and SampL is +1 (e.g., indicating that signal 220 is greater than both VREFH and VREFL), the decoder 225 may determine that

Symbol n has voltage level L3 (corresponding to symbol value +1). If SampH is −1 and SampL is +1 (e.g., indicating that signal 220 is less than VREFH and greater than VREFL), the decoder 225 may determine that Symbol n has voltage level L2 (corresponding to symbol value 0). If SampH is −1 and SampL is 11 (e.g., indicating that signal 220 is less than both VREFH and VREFL), the decoder 225 may determine that Symbol n has voltage level L1 (corresponding to symbol value −1).

Additional components may be added to the receive circuitry 200 to accommodate other PAM schemes. In general, for a PAMx scheme (where x is a positive integer) the quantity of amplifiers 205 may be x-1 and the quantity of sampling circuits may be x-1.

For example, if the system that includes the receive circuitry 200 uses PAM4, the receive circuitry 200 may include an additional amplifier (e.g., a third amplifier 205-c) and an additional sampling circuit (e.g., a third sampling circuit 210-c). The amplifier 205-c may function similar to the amplifier 205-a and the amplifier 205-b except that the amplifier 205-c may compare the signal 220 to a third reference signal (e.g., VREFU). So, at a high level, the amplifier 205-c may be configured to receive the signal 220, compare the signal 220 to the third reference voltage (e.g., VREFU), and output a third amplified signal (e.g., AmpU) based on the comparison. The amplifier 205-c may have a third propagation delay (e.g., TU) that is different than the propagation delays of the other amplifiers 205.

In addition to the third amplifier, the receive circuitry 200 may include a third sampling circuit (e.g., sampling circuit 210-c) that is coupled with the third amplifier. The sampling circuit 210-c may function similar to the sampling circuit 210-a and the sampling circuit 210-b except that the sampling circuit 210-c may sample the third amplified signal (e.g., AmpU) according to a third input clock (e.g., ClockU). The sampling circuit 210-c may output the sampled value (e.g., SampU) to the decoder 225 for decoding the corresponding PAM4 symbol.

Thus, the receive circuitry 200 may receive and process a multi-level signal using sampling circuits that are asynchronously operated, which may improve decoding of the multi-level signal.

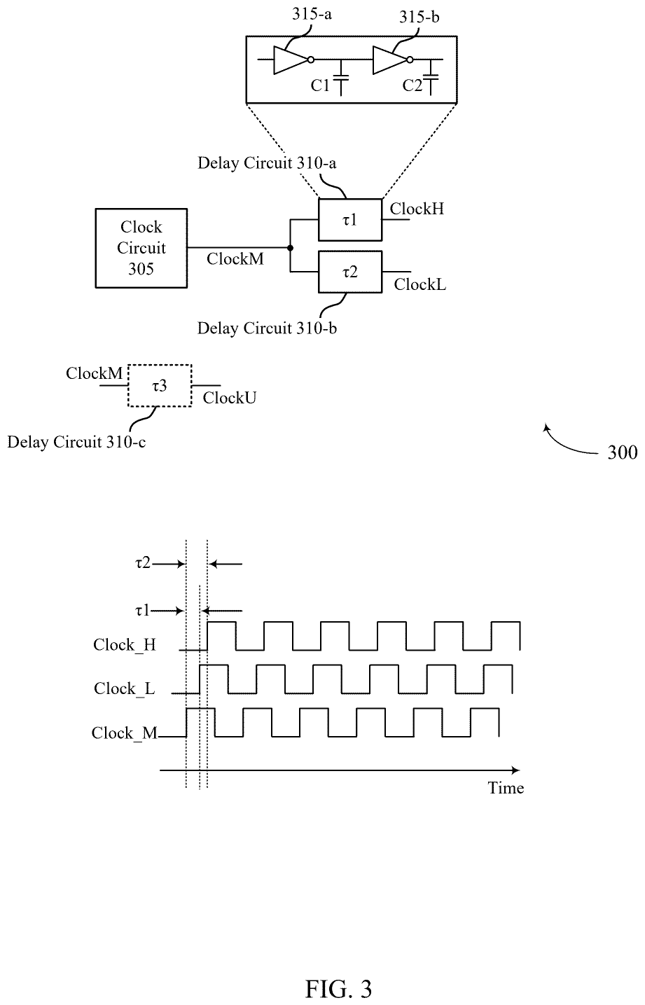

FIG. 3 shows an example of clock circuitry 300 that supports asynchronous multi-level signal sampling in accordance with examples as disclosed herein. The clock circuitry 300 may be an example of clock circuitry that is used by a system (e.g., a memory system, a host system) to generate the offset clock signals ClockH and ClockL for the sampling circuits 210. Accordingly, the clock circuitry 300 may be coupled with the sampling circuits 210. For example, the output terminal of delay circuit 310-a may be coupled with an input terminal of the sampling circuit 210-a so that the sampling circuit 210-a receives clock signal ClockH from delay circuit 310-a. Similarly, the output terminal of delay circuit 310-b may be coupled with an input terminal of the sampling circuit 210-b so that the sampling circuit 210-b receives clock signal ClockL from delay circuit 310-b.

The clock circuitry 300 may include clock circuit 305, which may be configured to generate a master clock signal (e.g., ClockM). The clock circuit 305 may be coupled with the delay circuits 310 so that the master clock signal ClockM is received by the delay circuits 310.

The delay circuits 310 may be configured to generate respective clock signals by delaying the master clock signal ClockM by different amounts. For example, the delay circuit 310-a may be configured to generate clock signal ClockH by delaying the master clock signal ClockM by a delay τ1. And the delay circuit 310-b may be configured to generate clock signal ClockL by delaying the master clock signal ClockM by a delay τ2. Thus, the rising edges (and falling edges) of the clock signal ClockH may be offset from the rising edges (and falling edges) of the master clock signal ClockM by delay τ1. And the rising edges (and falling edges) of the clock signal ClockL may be offset from the rising edges (and falling edges) of the master clock signal ClockM by delay τ2. Although offset in time, the clock signals ClockH and ClockL may have the same frequency and the same duty cycle, which may be the same frequency and duty cycle as the master clock signal ClockM.

The delays introduced by the delay circuits 310 may be based on (e.g., a function of, proportional to) the propagation delays of the amplifiers 205. For example, the delay τ1 may be based on the propagation delay τH of the amplifier 205-a and the delay τ2 may be based on the propagation delay τL of the amplifier 205-a. In some examples, the delay τ1 may be equal to the propagation delay τH and the delay τ2 may be equal to the propagation delay τL. In some examples, the difference between the delay τ1 and the delay τ2 may be equal to the difference between the propagation delay τH and the propagation delay τL.

In some examples, a delay circuit may include one or more inverters, one or more capacitive components, or both. For example, the delay circuit 310-a may include inverter 315-a and inverter 315-b. The inverters 315 may be in series with each other such that the output terminal of the inverter 315-a is coupled with the input terminal of the inverter 315-b. The delay circuit 310-a may also include capacitive component C1 (e.g., a first capacitor) and capacitive component C2 (e.g., a second capacitor). The capacitive components may have adjustable capacitances. The delay circuit 310-b may be configured similarly to the delay circuit 310-a but may have different quantities of inverters and capacitive components relative to the delay circuit 310-a, have inverters and capacitive components with different intrinsic characteristics relative to the delay circuit 310-a, or both.

In some examples, the clock signals may be generated by different clock circuits 305. For example, a first clock circuit 305 may generate clock signal ClockH and a second clock circuit 305 may generate clock signal ClockL.

Additional components may be added to the clock circuitry 300 to accommodate other PAM schemes. In general, for a PAMx scheme (where x is a positive integer) the quantity of delay circuits 310 may be x-1. For example, if the system that includes the clock circuitry 300 uses PAM4, the clock circuitry 300 may include a third delay circuit (e.g., delay circuit 310-c). The delay circuit 310-c may be configured to generate clock signal ClockU by delaying the master clock signal ClockM by a delay τ3, which may be based on the propagation delay TU of the amplifier 205-c.

Thus, the clock circuitry 300 may generate clock signals that are offset in time, which may enable asynchronous sampling of multi-level signals as described herein.

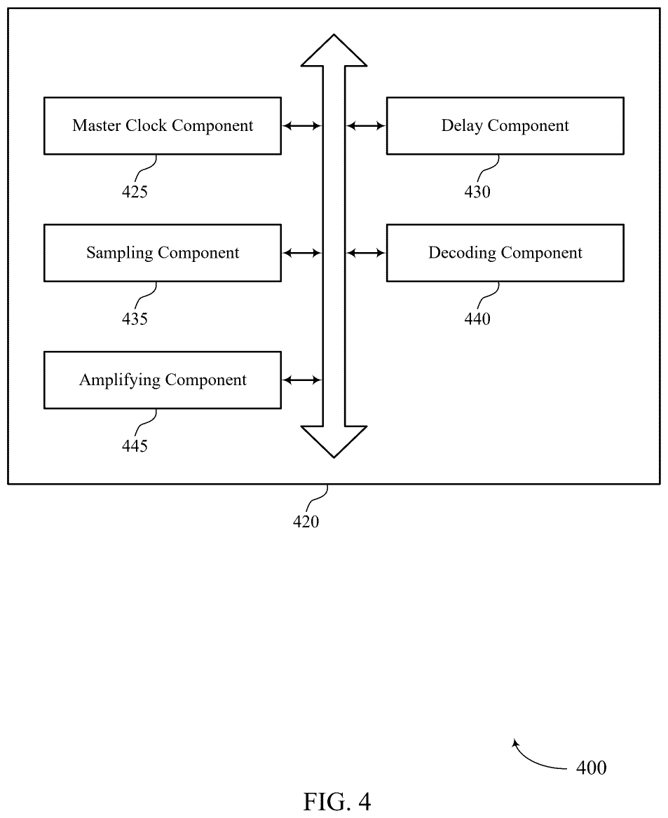

FIG. 4 shows a block diagram 400 of a memory system 420 that supports asynchronous multi-level signal sampling in accordance with examples as disclosed herein. The memory system 420 may be an example of aspects of a memory system as described with reference to FIGS. 1 through 3. The memory system 420, or various components thereof, may be an example of means for performing various aspects of asynchronous multi-level signal sampling as described herein. For example, the memory system 420 may include a master clock component 425, a delay component 430, a sampling component 435, a decoding component 440, an amplifying component 445, or any combination thereof. Each of these components, or components of subcomponents thereof (e.g., one or more processors, one or more memories), may communicate, directly or indirectly, with one another (e.g., via one or more buses).

The master clock component 425 may be configured as or otherwise support a means for generating a master clock signal for a memory system. The delay component 430 may be configured as or otherwise support a means for generating a first clock signal by delaying the master clock signal by a first duration that is based at least in part on a first propagation delay associated with a first amplifier configured to amplify a voltage difference between a received data signal and a first reference voltage. In some examples, the delay component 430 may be configured as or otherwise support a means for generating a second clock signal by delaying the master clock signal by a second duration that is based at least in part on a second propagation delay associated with a second amplifier configured to amplify a voltage difference between the received data signal and a second reference voltage. The sampling component 435 may be configured as or otherwise support a means for sampling, by a first sampling circuit based at least in part on the first clock signal, a first amplified data signal outputted by the first amplifier. In some examples, the sampling component 435 may be configured as or otherwise support a means for sampling, by a second sampling circuit based at least in part on the second clock signal, a second amplified data signal outputted by the second amplifier.

In some examples, the decoding component 440 may be configured as or otherwise support a means for determining a symbol value for the data signal based at least in part on a first sampled value of the first amplified data signal and on a second sampled value of the second amplified data signal.

In some examples, the master clock component 425 may be configured as or otherwise support a means for inputting the master clock signal into first delay circuit configured to delay the master clock signal by the first duration, where the first clock signal is generated by the first delay circuit. In some examples, the master clock component 425 may be configured as or otherwise support a means for inputting the master clock signal into a second delay circuit configured to delay the master clock signal by the second duration, where the second clock signal is generated by the second delay circuit.

In some examples, the amplifying component 445 may be configured as or otherwise support a means for inputting the first clock signal into the first sampling circuit, where the first amplified data signal is sampled based at least in part on inputting the first clock signal into the first sampling circuit. In some examples, the amplifying component 445 may be configured as or otherwise support a means for inputting the second clock signal into the second sampling circuit, where the second amplified data signal is sampled based at least in part on inputting the second clock signal into the second sampling circuit.

In some examples, the delay component 430 may be configured as or otherwise support a means for generating a third clock signal by delaying the master clock signal by a third duration that is based at least in part on a third propagation delay associated with a third amplifier configured to amplify a voltage difference between the received data signal and a third reference voltage. In some examples, the sampling component 435 may be configured as or otherwise support a means for sampling, by a third sampling circuit based at least in part on the third clock signal, a third amplified data signal outputted by the third amplifier.

In some examples, the data signal includes a pulse amplitude modulated (PAM) signal including a highest voltage level, a middle voltage level, and a lowest voltage level.

In some examples, the first reference voltage is between the highest voltage level of the data signal and the middle voltage level of the data signal. In some examples, the second reference voltage is between the middle voltage level of the data signal and the lowest voltage level of the data signal.

In some examples, the first clock signal and the second clock signal have a same frequency and a same duty cycle.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

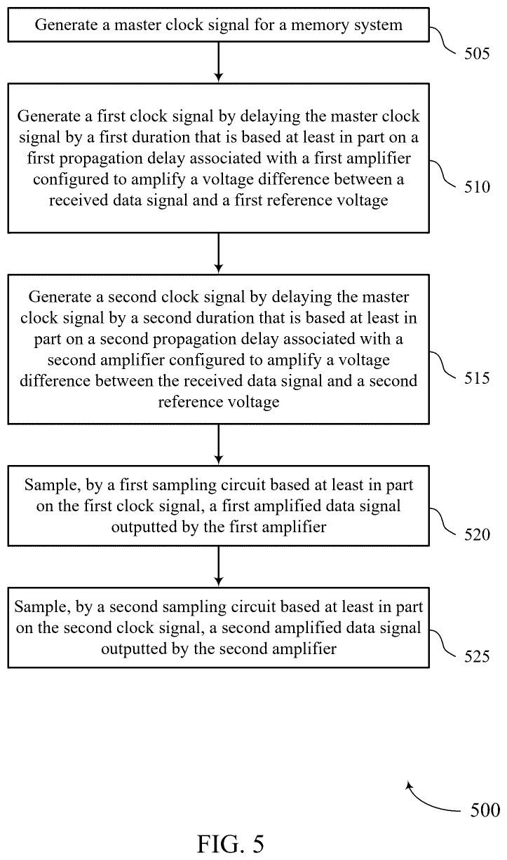

FIG. 5 shows a flowchart illustrating a method 500 that supports asynchronous multi-level signal sampling in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include generating a master clock signal for a memory system. In some examples, aspects of the operations of 505 may be performed by a master clock component 425 as described with reference to FIG. 4.

At 510, the method may include generating a first clock signal by delaying the master clock signal by a first duration that is based at least in part on a first propagation delay associated with a first amplifier configured to amplify a voltage difference between a received data signal and a first reference voltage. In some examples, aspects of the operations of 510 may be performed by a delay component 430 as described with reference to FIG. 4.

At 515, the method may include generating a second clock signal by delaying the master clock signal by a second duration that is based at least in part on a second propagation delay associated with a second amplifier configured to amplify a voltage difference between the received data signal and a second reference voltage. In some examples, aspects of the operations of 515 may be performed by a delay component 430 as described with reference to FIG. 4.

At 520, the method may include sampling, by a first sampling circuit based at least in part on the first clock signal, a first amplified data signal outputted by the first amplifier. In some examples, aspects of the operations of 520 may be performed by a sampling component 435 as described with reference to FIG. 4.

At 525, the method may include sampling, by a second sampling circuit based at

least in part on the second clock signal, a second amplified data signal outputted by the second amplifier. In some examples, aspects of the operations of 525 may be performed by a sampling component 435 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for generating a master clock signal for a memory system; generating a first clock signal by delaying the master clock signal by a first duration that is based at least in part on a first propagation delay associated with a first amplifier configured to amplify a voltage difference between a received data signal and a first reference voltage; generating a second clock signal by delaying the master clock signal by a second duration that is based at least in part on a second propagation delay associated with a second amplifier configured to amplify a voltage difference between the received data signal and a second reference voltage; sampling, by a first sampling circuit based at least in part on the first clock signal, a first amplified data signal outputted by the first amplifier; and sampling, by a second sampling circuit based at least in part on the second clock signal, a second amplified data signal outputted by the second amplifier.

Aspect 2: The method, apparatus, or non-transitory computer-readable medium of aspect 1, further including operations, features, circuitry, logic, means, or instructions, or any combination thereof for determining a symbol value for the data signal based at least in part on a first sampled value of the first amplified data signal and on a second sampled value of the second amplified data signal.

Aspect 3: The method, apparatus, or non-transitory computer-readable medium of any of aspects 1 through 2, further including operations, features, circuitry, logic, means, or instructions, or any combination thereof for inputting the master clock signal into first delay circuit configured to delay the master clock signal by the first duration, where the first clock signal is generated by the first delay circuit and inputting the master clock signal into a second delay circuit configured to delay the master clock signal by the second duration, where the second clock signal is generated by the second delay circuit.

Aspect 4: The method, apparatus, or non-transitory computer-readable medium of aspect 3, further including operations, features, circuitry, logic, means, or instructions, or any combination thereof for inputting the first clock signal into the first sampling circuit, where the first amplified data signal is sampled based at least in part on inputting the first clock signal into the first sampling circuit and inputting the second clock signal into the second sampling circuit, where the second amplified data signal is sampled based at least in part on inputting the second clock signal into the second sampling circuit.

Aspect 5: The method, apparatus, or non-transitory computer-readable medium of any of aspects 1 through 4, further including operations, features, circuitry, logic, means, or instructions, or any combination thereof for generating a third clock signal by delaying the master clock signal by a third duration that is based at least in part on a third propagation delay associated with a third amplifier configured to amplify a voltage difference between the received data signal and a third reference voltage and sampling, by a third sampling circuit based at least in part on the third clock signal, a third amplified data signal outputted by the third amplifier.

Aspect 6: The method, apparatus, or non-transitory computer-readable medium of any of aspects 1 through 5, where the data signal includes a pulse amplitude modulated (PAM) signal including a highest voltage level, a middle voltage level, and a lowest voltage level.

Aspect 7: The method, apparatus, or non-transitory computer-readable medium of aspect 6, where the first reference voltage is between the highest voltage level of the data signal and the middle voltage level of the data signal and the second reference voltage is between the middle voltage level of the data signal and the lowest voltage level of the data signal.

Aspect 8: The method, apparatus, or non-transitory computer-readable medium of any of aspects 1 through 7, where the first clock signal and the second clock signal have a same frequency and a same duty cycle.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: An apparatus, including: a clock circuit configured to generate a master clock signal; a first delay circuit configured to output a first clock signal by being configured to delay the master clock signal by a first duration that is based at least in part on a first propagation delay associated with a first amplifier configured to receive a data signal; a second delay circuit configured to output a second clock signal by being configured to delay the master clock signal by a second duration that is based at least in part on a second propagation delay associated with a second amplifier configured to receive the data signal; a first sampling circuit configured to sample, based at least in part on the first clock signal, a first amplified data signal outputted by the first amplifier; and a second sampling circuit configured to sample, based at least in part on the second clock signal, a second amplified data signal outputted by the second amplifier.

Aspect 10: The apparatus, of aspect 9, further including: a decoder configured to determine a symbol value for the data signal based at least in part on a first sampled value of the first amplified data signal and on a second sampled value of the second amplified data signal.

Aspect 11: The apparatus, of any of aspects 9 through 10, where the first delay circuit includes one or more inverters, and the second delay circuit includes one or more inverters.

Aspect 12: The apparatus of any of aspects 9 through 11, where the first sampling circuit is coupled with the first amplifier and the first delay circuit, and the second sampling circuit is coupled with the second amplifier and the second delay circuit.

Aspect 13: The apparatus of any of aspects 9 through 12, where a first input terminal of the first amplifier is coupled with a second input terminal of the second amplifier, and the first input terminal and the second input terminal are configured to receive the data signal.

Aspect 14: The apparatus, of any of aspects 9 through 13, where the first amplifier is configured to amplify a voltage difference between the data signal and a first reference voltage, and the second amplifier is configured to amplify a voltage difference between the data signal and a second reference voltage.

Aspect 15: The apparatus of aspect 14, where the data signal includes a pulse amplitude modulated (PAM) signal including a highest voltage level, a middle voltage level, and a lowest voltage level, the first reference voltage is between the highest voltage level of the data signal and the middle voltage level of the data signal, and the second reference voltage is between the middle voltage level of the data signal and the lowest voltage level of the data signal.

Aspect 16: The apparatus of any of aspects 9 through 15, further including: a third delay circuit configured to output a third clock signal by being configured to delay the master clock signal by a third duration that is based at least in part on a third propagation delay associated with a third amplifier configured to receive the data signal; and a third sampling circuit configured to sample, based at least in part on the third clock signal, a third amplified data signal outputted by the third amplifier.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
generating a master clock signal for a memory system;
generating a first clock signal by delaying the master clock signal by a first duration that is based at least in part on a first propagation delay associated with a first amplifier configured to amplify a voltage difference between a received data signal and a first reference voltage;
generating a second clock signal by delaying the master clock signal by a second duration that is based at least in part on a second propagation delay associated with a second amplifier configured to amplify a voltage difference between the received data signal and a second reference voltage;
sampling, by a first sampling circuit based at least in part on the first clock signal, a first amplified data signal outputted by the first amplifier; and
sampling, by a second sampling circuit based at least in part on the second clock signal, a second amplified data signal outputted by the second amplifier.

2. The method of claim 1, further comprising:
determining a symbol value for the data signal based at least in part on a first sampled value of the first amplified data signal and on a second sampled value of the second amplified data signal.

3. The method of claim 1, further comprising:
inputting the master clock signal into first delay circuit configured to delay the master clock signal by the first duration, wherein the first clock signal is generated by the first delay circuit; and
inputting the master clock signal into a second delay circuit configured to delay the master clock signal by the second duration, wherein the second clock signal is generated by the second delay circuit.

4. The method of claim 3, further comprising:
inputting the first clock signal into the first sampling circuit, wherein the first amplified data signal is sampled based at least in part on inputting the first clock signal into the first sampling circuit; and
inputting the second clock signal into the second sampling circuit, wherein the second amplified data signal is sampled based at least in part on inputting the second clock signal into the second sampling circuit.

5. The method of claim 1, further comprising:
generating a third clock signal by delaying the master clock signal by a third duration that is based at least in part on a third propagation delay associated with a third amplifier configured to amplify a voltage difference between the received data signal and a third reference voltage; and
sampling, by a third sampling circuit based at least in part on the third clock signal, a third amplified data signal outputted by the third amplifier.

6. The method of claim 1, wherein the data signal comprises a pulse amplitude modulated (PAM) signal comprising a highest voltage level, a middle voltage level, and a lowest voltage level.

7. The method of claim 6, wherein the first reference voltage is between the highest voltage level of the data signal and the middle voltage level of the data signal, and wherein the second reference voltage is between the middle voltage level of the data signal and the lowest voltage level of the data signal.

8. The method of claim 1, wherein the first clock signal and the second clock signal have a same frequency and a same duty cycle.

9. An apparatus, comprising:
a clock circuit configured to generate a master clock signal;
a first delay circuit configured to output a first clock signal by being configured to delay the master clock signal by a first duration that is based at least in part on a first propagation delay associated with a first amplifier configured to receive a data signal;
a second delay circuit configured to output a second clock signal by being configured to delay the master clock signal by a second duration that is based at least in part on a second propagation delay associated with a second amplifier configured to receive the data signal;
a first sampling circuit configured to sample, based at least in part on the first clock signal, a first amplified data signal outputted by the first amplifier; and
a second sampling circuit configured to sample, based at least in part on the second clock signal, a second amplified data signal outputted by the second amplifier.

10. The apparatus, of claim 9, further comprising:
a decoder configured to determine a symbol value for the data signal based at least in part on a first sampled value of the first amplified data signal and on a second sampled value of the second amplified data signal.

11. The apparatus, of claim 9, wherein the first delay circuit comprises one or more inverters, and wherein the second delay circuit comprises one or more inverters.

12. The apparatus of claim 9, wherein the first sampling circuit is coupled with the first amplifier and the first delay circuit, and wherein the second sampling circuit is coupled with the second amplifier and the second delay circuit.

13. The apparatus of claim 9, wherein a first input terminal of the first amplifier is coupled with a second input terminal of the second amplifier, and wherein the first input terminal and the second input terminal are configured to receive the data signal.

14. The apparatus, of claim 9, wherein the first amplifier is configured to amplify a voltage difference between the data signal and a first reference voltage, and wherein the second amplifier is configured to amplify a voltage difference between the data signal and a second reference voltage.

15. The apparatus of claim 14, wherein the data signal comprises a pulse amplitude modulated (PAM) signal comprising a highest voltage level, a middle voltage level, and a lowest voltage level, wherein the first reference voltage is between the highest voltage level of the data signal and the middle voltage level of the data signal, and wherein the second reference voltage is between the middle voltage level of the data signal and the lowest voltage level of the data signal.

16. The apparatus of claim 9, further comprising:
a third delay circuit configured to output a third clock signal by being configured to delay the master clock signal by a third duration that is based at least in part on a third propagation delay associated with a third amplifier configured to receive the data signal; and
a third sampling circuit configured to sample, based at least in part on the third clock signal, a third amplified data signal outputted by the third amplifier.

17. A non-transitory computer-readable medium storing code comprising instructions which, when executed by one or more processors of an apparatus, cause the apparatus to:
generate a master clock signal for a memory system;
generate a first clock signal by delaying the master clock signal by a first duration that is based at least in part on a first propagation delay associated with a first amplifier configured to amplify a voltage difference between a received data signal and a first reference voltage;
generate a second clock signal by delaying the master clock signal by a second duration that is based at least in part on a second propagation delay associated with a second amplifier configured to amplify a voltage difference between the received data signal and a second reference voltage;
sample, by a first sampling circuit based at least in part on the first clock signal, a first amplified data signal outputted by the first amplifier; and
sample, by a second sampling circuit based at least in part on the second clock signal, a second amplified data signal outputted by the second amplifier.

18. The non-transitory computer-readable medium of claim 17, wherein the instructions, when executed by the one or more processors of the apparatus, cause the apparatus to:
determine a symbol value for the data signal based at least in part on a first sampled value of the first amplified data signal and on a second sampled value of the second amplified data signal.

19. The non-transitory computer-readable medium of claim 17, wherein the instructions, when executed by the one or more processors of the apparatus, cause the apparatus to:
input the master clock signal into first delay circuit configured to delay the master clock signal by the first duration, wherein the first clock signal is generated by the first delay circuit; and
input the master clock signal into a second delay circuit configured to delay the master clock signal by the second duration, wherein the second clock signal is generated by the second delay circuit.

20. The non-transitory computer-readable medium of claim 19, wherein the instructions, when executed by the one or more processors of the apparatus, cause the apparatus to:
input the first clock signal into the first sampling circuit, wherein the first amplified data signal is sampled based at least in part on inputting the first clock signal into the first sampling circuit; and
input the second clock signal into the second sampling circuit, wherein the second amplified data signal is sampled based at least in part on inputting the second clock signal into the second sampling circuit.

21. The non-transitory computer-readable medium of claim 17, wherein the instructions, when executed by the one or more processors of the apparatus, cause the apparatus to:
generate a third clock signal by delaying the master clock signal by a third duration that is based at least in part on a third propagation delay associated with a third amplifier configured to amplify a voltage difference between the received data signal and a third reference voltage; and
sample, by a third sampling circuit based at least in part on the third clock signal, a third amplified data signal outputted by the third amplifier.

22. The non-transitory computer-readable medium of claim 17, wherein the data signal comprises a pulse amplitude modulated (PAM) signal comprising a highest voltage level, a middle voltage level, and a lowest voltage level.

23. The non-transitory computer-readable medium of claim 22, wherein the first reference voltage is between the highest voltage level of the data signal and the middle voltage level of the data signal, and the second reference voltage is between the middle voltage level of the data signal and the lowest voltage level of the data signal.
